(19) United States
(12) Patent Application Publication
(10) Pub. No.: US 2008/0224212 A1
(43) Pub. Date: Sep. 18, 2008

(54) SEMICONDUCTOR DEVICE AND METHOD FOR FABRICATING THE SAME

(75) Inventors: Young-Ho LEE, Ichon-shi (KR); Dong-Sun Sheen, Ichon-shi (KR); Seok-Pyo Song, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/965,559

(22) Filed: Dec. 27, 2007

(30) Foreign Application Priority Data
Mar. 16, 2007 (KR) 10-2007-0026086

(51) Int. Cl. H01L 29/78; H01L 21/336

(52) U.S. Cl. 257/344; 438/300; 257/E21.437; 257/E29.266

(57) ABSTRACT

A method for fabricating a semiconductor device is provided. A first insulation layer and a second insulation layer are formed over the substrate having a gate. A spacer etching process is performed to form an etched first insulation layer and an etched second insulation layer. The etched first insulation layer partially protrudes from the substrate and contacts sidewalls of the gate. The etched second insulation layer is removed through a selective epitaxial growth (SEG) process that forms an epitaxial layer over the exposed substrate. One of facets of the epitaxial layer is formed on the protruding portion of the etched first insulation layer. A third insulation layer is formed on sidewalls of the etched first insulation layer and the one of the facets of the epitaxial layer is covered by the third insulation layer.

### CROSS-REFERENCE TO RELATED APPLICATIONS

The present invention claims priority of Korean patent application number 10-2007-0026086, filed on Mar. 16, 2007, which is incorporated by reference in its entirety.

### BACKGROUND OF THE INVENTION

The present invention relates to a method for fabricating a semiconductor device, and more particularly, to a method for fabricating a semiconductor device including a transistor with an elevated source/drain (ESD) structure.

As semiconductor devices become highly integrated, a transistor of a semiconductor device is scaled down. Since the scale-down of the transistor reduces a gate effective channel length, a short channel effect such as a punch through between a source and a drain is caused. Thus, a shallow junction is formed to prevent the short channel effect.

A lightly doped drain (LDD) process or a low energy ion implantation process is used for forming the shallow junction, but there is a limitation in its application. Recently, a selective epitaxial growth (SEG) process is used for fabricating a transistor having an elevated source/drain (ESD) structure.

A method for fabricating a transistor having an ESD structure using a SEG process and its limitations will be described hereinafter referring to FIGS. 1A to 1D.

FIGS. 1A to 1D illustrate cross-sectional views of a method for fabricating a typical transistor having an ESD structure.

Referring to FIG. 1A, a gate 13 is formed over a substrate 11 having an isolation layer 12. The gate 13 may have a stacked structure of a gate insulation layer, a conductive layer, and a gate hard mask.

Referring to FIG. 1B, a LDD mask 14 is formed to cover the top surface and both sidewalls of the gate 13. A LDD ion implantation is performed on the exposed substrate 11 to form a LDD region 15. A formation of the LDD region 15 where low-concentration impurity ions are implanted can prevent a local concentration of an electric field and prevent a short channel effect that reduces a threshold voltage due to a reduced channel length.

Referring to FIG. 1C, the LDD mask 14 is removed. A nitride layer and an oxide layer for a gate spacer are formed over the substrate 11 where the gate 13 is formed. A spacer etch process is performed on a resulting structure to form a gate spacer 16 including an etched nitride layer 16A and an etched oxide layer 16B on sidewalls of the gate 13.

For the ESD structure, a selective epitaxial growth (SEG) process is performed to form an epitaxial layer 17 over the exposed substrate 11. Facets A are formed at edges of the epitaxial layer 17 due to characteristics of the SEG process. A depth of a source/drain ion implant region (FIG. 1D) is locally deep due to the facets A. The source/drain ion implant region 18 is formed by a subsequent source/drain ion implantation process.

Referring to FIG. 1D, the source/drain ion implantation is performed by using the gate 13 and the gate spacer 16 as an ion implantation mask, thereby forming the source/drain ion implant region 18. Since the epitaxial layer 17 has been already formed by the process of FIG. 1C, it is possible to form a shallow junction. The LDD region 15, the epitaxial layer 17 and the source/drain ion implant region 18 are formed the ESD structure.

In order to form the epitaxial layer in accordance with the SEG process, a cleaning process should be performed to remove a native oxide layer formed on the substrate prior to a formation of the epitaxial layer. However, since the cleaning process is generally performed by using a fluorine-based gas or liquid, the oxide layer for the gate spacer may sustain a loss. Furthermore, as the facets are generated at the edges of the epitaxial layer due to the characteristics of the SEG process, the depth of the source/drain region may be varied.

Referring to FIG. 3, a thickness of the gate spacer 160 on the sidewalls of the gate 130 is difficult to be controlled because of the loss of the oxide layer. Thus, it is difficult to control the facets A′ of the epitaxial layer 170 on the sides of the gate spacer 160. Since varying of the depth of the source/drain region is difficult to be controlled when controlling the facets A′ of the epitaxial layer 170 is difficult, the characteristics of the semiconductor devices may be deteriorated.

Referring to FIG. 4, a gate spacer 161 may be formed by merely using a nitride layer. Herein, the nitride layer does not sustain a loss even though a cleaning process is performed. Thus, a thickness of the gate spacer 161 can be constantly maintained. However, facets A″ is generated in an epitaxial layer 171 on the sides of the gate spacer 161 and controlling a generation of the facets A″ is difficult. Consequently, it is still difficult to control the depth of the source/drain region.

### SUMMARY OF THE INVENTION

The present invention is directed to provide a method for fabricating a semiconductor device, and more particularly, to a method for fabricating a transistor in a semiconductor device and fabricating the same. In the transistor, the thickness of a gate spacer and facets can be constantly controlled and the influence of the facets can be prevented. Therefore, a source/drain region formed by a source/drain ion implantation can be formed with the constant depth, thereby ensuring stable characteristics of the semiconductor device having an elevated source/drain (ESD) structure.

In accordance with an aspect of the present invention, there is provided a method for fabricating a semiconductor device. The method, includes forming a gate over a substrate; sequentially forming a first insulation layer and a second insulation layer over the substrate having the gate, and performing a spacer etching process to form an etched first insulation layer and an etched second insulation layer. The etched first insulation layer partially protrudes from the substrate and contacting sidewalls of the gate. The method further includes removing the etched second insulation layer, performing a selective epitaxial growth (SEG) process to form an epitaxial layer over the exposed substrate, one of facets of the epitaxial layer being formed on the protruding portion of the etched first insulation layer, and forming a third insulation layer on sidewalls of the etched first insulation layer. The third insulation layer covers the one of the facets of the epitaxial layer.

In accordance with another aspect of the present invention, there is provided a semiconductor device that includes a substrates gate formed over the substrate, gate spacers formed on sidewalls of the gate, a source/drain region defined on both sides of the gate spacers by a selective growth of an epitaxial layer and elevated higher than an initial top surface of the substrate. The gate spacers include an etched first insulation layer contacting the sidewalls of the gate and partially protruding from the substrate, and an etched third insulation layer contacting sidewalls of the etched first insulation layer. One of facets of the epitaxial layer is formed on the protruding portion of the etched first insulation layer and is covered by the etched third insulation layer.

### BRIEF DESCRIPTION OF THE DRAWINGS

FIGS. 1A to 1D illustrate cross-sectional views of a method for fabricating a typical transistor.

FIGS. 2A to 2G illustrate cross-sectional views of a method for fabricating a transistor in accordance with an embodiment of the present invention.

FIG. 3 illustrates a cross-sectional view of a limitation of the typical transistor.

FIG. 4 illustrates a cross-sectional view of another limitation of the typical transistor.

FIG. 5 illustrates a cross-sectional view of the transistor in accordance with an embodiment of the present invention.

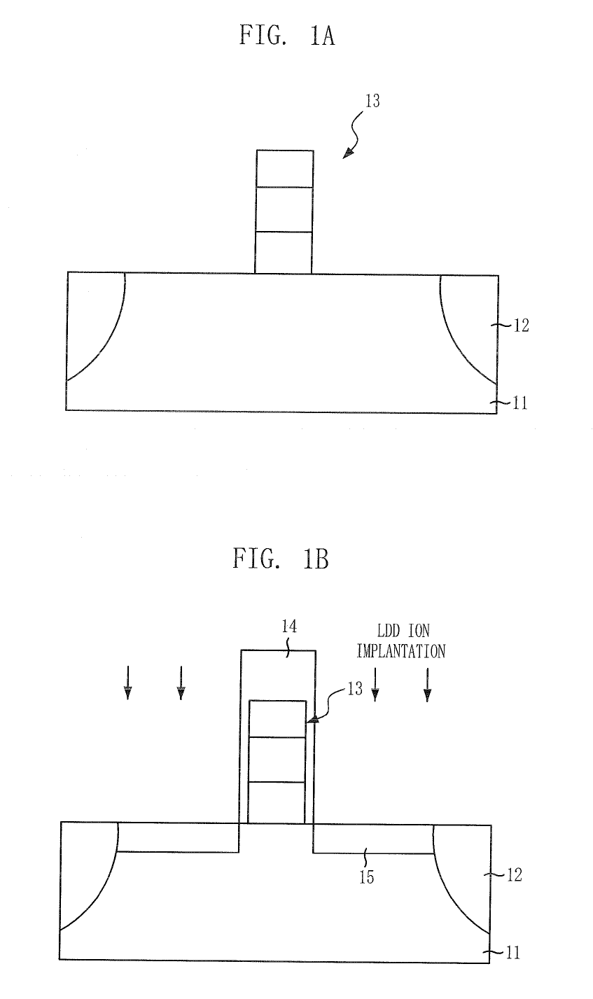

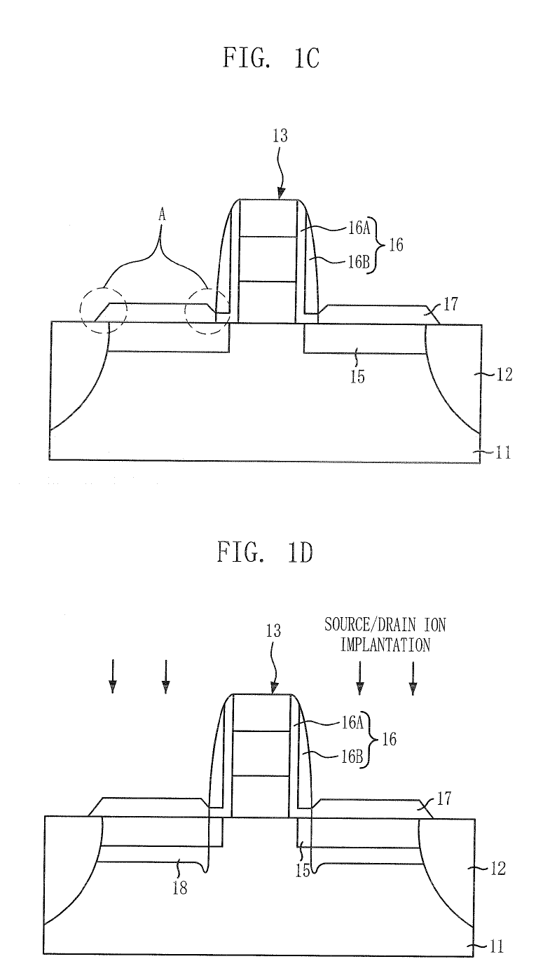

### DESCRIPTION OF SPECIFIC EMBODIMENTS

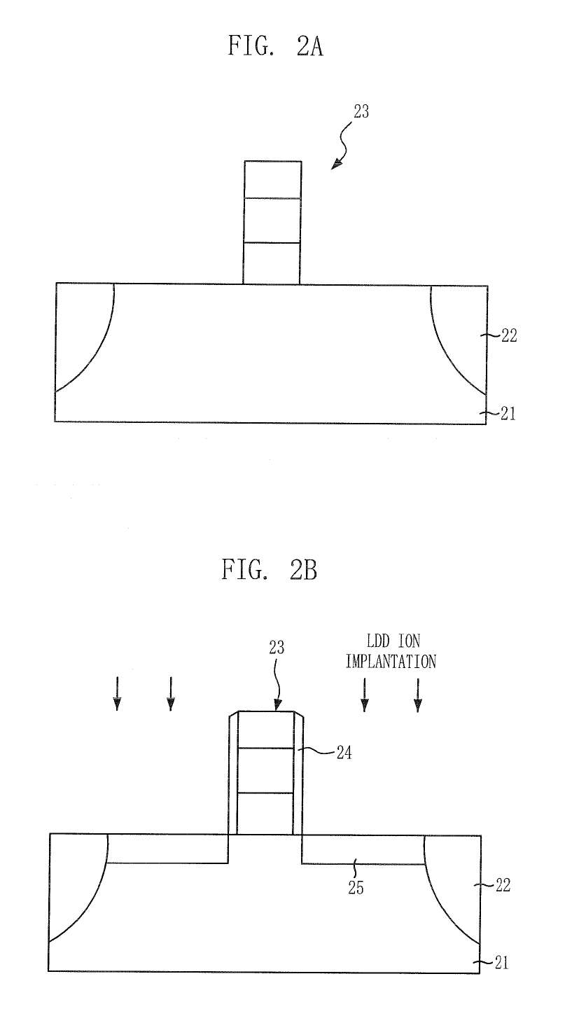

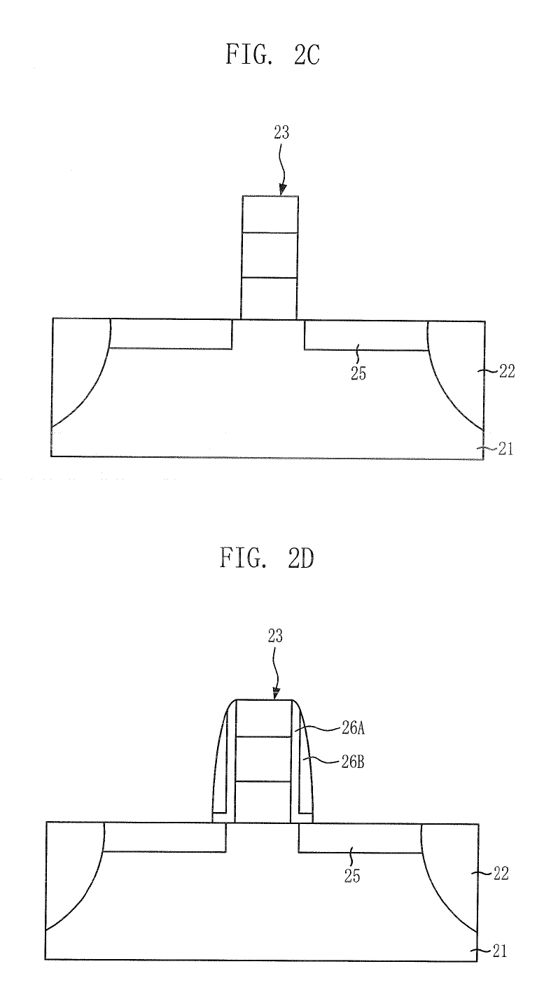

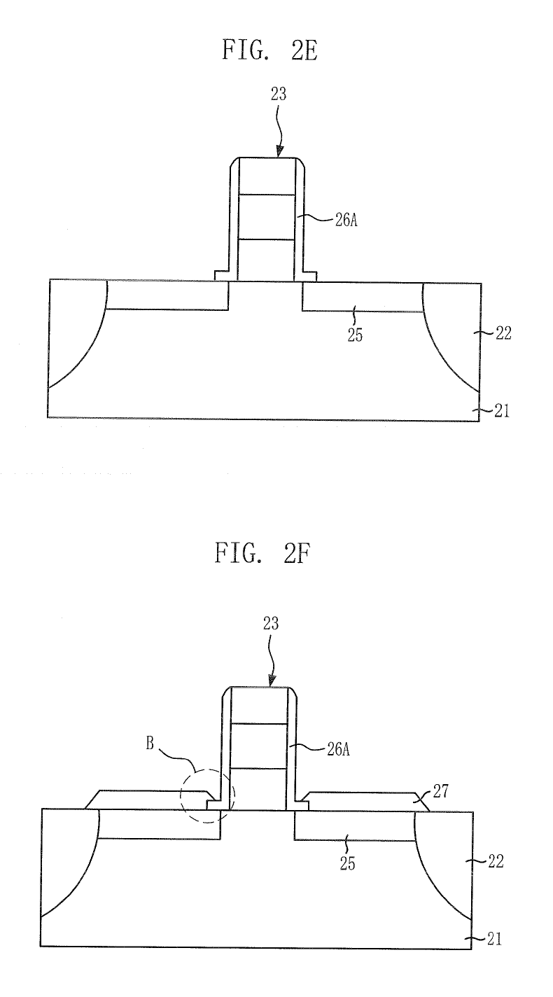

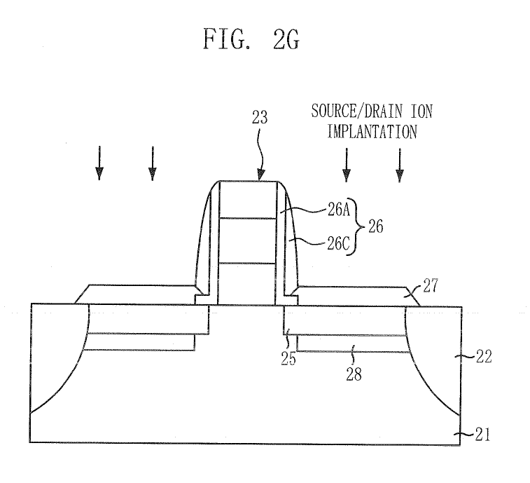

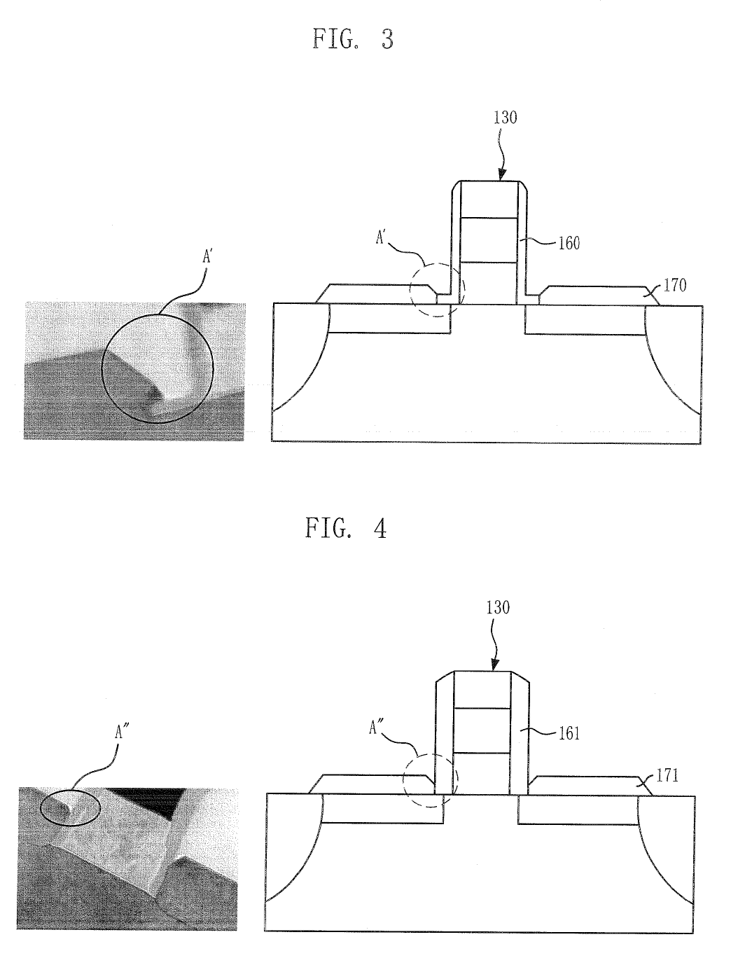

FIGS. 2A to 2G illustrate cross-sectional views of a method for fabricating a transistor in accordance with an embodiment of the present invention.

Referring to FIG. 2A, a gate 23 is formed over a substrate 21 having an isolation layer 22. The gate 23 may have a stacked structure of a gate insulation layer, a conductive layer, and a gate hard mask.

Referring to FIG. 2B, a first gate spacer 24 used as an insulation layer is formed by using an oxide layer on both sidewalls of the gate 23. A lightly doped drain (LDD) ion implantation is performed on the exposed substrate 21 to form a LDD region 25. The first gate spacer 24 is formed by using a low pressure chemical vapor deposition (LPCVD) process or plasma enhanced chemical vapor deposition (PECVD) process on the substrate 21 with the gate 23. Subsequently, a first spacer etching process is performed by adjusting a predetermined width of the LDD region 25 on the first gate spacer 24.

The typical LDD ion implantation is generally performed by using a LDD mask. On the other hand, in accordance with the embodiment of the present invention, a self-aligned LDD region is formed by using the first gate spacer 24. Therefore, a misalign due to the LDD mask process can be prevented. The LDD ion implantation is performed by controlling a degree of ions, dose, energy, and so on, according to the characteristics of the semiconductor devices.

Referring to FIG. 2C, the first gate spacer 24 (FIG. 2B) is removed. The removing of the first gate spacer 24 may be performed by a wet cleaning process or a dry cleaning process.

Referring to FIG. 2D, a nitride layer used as a first insulation layer and a first oxide layer used as a second insulation layer are sequentially formed over the substrate 21 having the gate 23. A second spacer etching process is performed on the first oxide layer used as the second insulation layer. Consequently, the etched nitride layer 26A used as the first insulation layer partially protruding from the substrate 21 is formed on sidewalls of the gate 23, and the etched first oxide layer 26B is formed on the sidewalls and the protruding portion of the etched nitride layer 26A. A cleaning process using sulfuric peroxide mixture (SPM) or ammonium peroxide mixture (APM) is performed to remove a polymer formed in the second spacer etching process.

Referring to FIG. 2E, the etched first oxide layer 26B is removed to control a thickness of the gate spacer and control a formation of the facets since controlling the thickness of the gate spacers and controlling the formation of the facets are difficult in the typical method due to the loss of the oxide layer. The removing of the etched first oxide layer 26B may be performed by the succeeding cleaning process prior to a subsequent formation of an epitaxial layer in order to remove a native oxide layer from a surface of the substrate 21. The cleaning process may be performed by using a fluorine-based gas or liquid.

Referring to FIG. 2F, a selective epitaxial growth (SEG) process is performed to form an epitaxial layer 27 over the exposed substrate 21 in order to form an elevated source/drain (ESD) structure. The epitaxial layer 27 is formed to have a predetermined thickness except edges and facets are formed at edges of the epitaxial layer 27 due to characteristics of the SEG process. Furthermore, one of the facets B is formed on the protruding portion of the etched nitride layer 26A. The epitaxial layer 27 is uniformly formed except the facests. The epitaxial layer 27 may be formed by using a low pressure chemical vapor deposition (LPCVD) apparatus, a very low pressure CVD (VLPCVD) apparatus, a plasma enhanced CVD (PECVD) apparatus, an ultra high vacuum CVD (UHVCVD) apparatus, a rapid thermal CVD (RTCVD) apparatus, or an atmosphere pressure CVD (APCVD). Furthermore, the epitaxial layer 27 may include a doped silicon layer, an undoped silicon layer, a doped silicon germanium, or an undoped silicon germanium.

Referring to FIG. 2G, a second oxide layer 26C used as a third insulation layer is formed on the sidewalls of the etched nitride layer 26A to cover the facet B of the epitaxial layer 27, thereby forming a second gate spacer 26 including the etched nitride layer 26A and the second oxide layer 26C. As described above, since the facet B of the epitaxial layer 27 is formed on the protruding portion of the etched nitride layer 26A, the second oxide layer 26C can easily cover the facet B.

A source/drain ion implantation is performed to form a source/drain ion implant region 28. The source/drain ion implantation is performed by controlling a degree of ions, dose, energy, and so on according to the characteristics of the semiconductor devices. Since the epitaxial layer 27 is uniformly formed except the facets and the facet B of the epitaxial layer 27 is covered with the second oxide layer 26C, the influence of the facet B is eliminated. Therefore, the depth of the source/drain ion implant region 28 can be constant. Furthermore, the shallow junction can be formed and the stable device characteristics can be ensured.

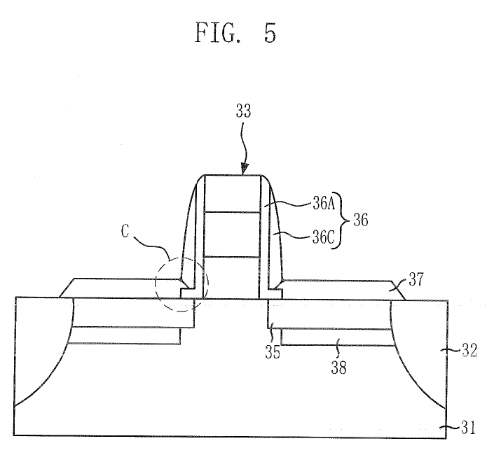

FIG. 5 illustrates a cross-sectional view of a transistor in accordance with an embodiment of the present invention. A gate 33 is formed over a substrate 31 having an isolation layer 32. A LDD region 35 is formed by performing a LDD ion implantation on the substrate 31. A gate spacer 36 is formed on the sidewalls of the gate 33. The gate spacer 36 includes an etched nitride layer 36A and a second oxide layer 36C. The etched nitride layer 36A is formed on the sidewalls of the gate 33 and partially protruding from the surface of the substrate 31. The second oxide layer 36C is formed on the sidewalls of the etched nitride layer 36A.

A SEG process is performed to form an epitaxial layer 37 on both sides of the gate spacer 36. One of facets C on edges of the epitaxial layer 37 is formed on the protruding portion of the etched nitride layer 36A and is covered with the second oxide layer 36C.

Due to the epitaxial layer 37, a source/drain ion implant region 38 is formed on both sides of the gate spacer 36. The LDD region 35, the epitaxial layer 37 and the source/drain ion implant region 38 are formed the ESD structure. The ESD structure including the LDD region 35, the epitaxial layer 37 and the source/drain ion implant region 38 is elevated so the ESD structure is higher than the initial top surface of the substrate 31 while the source/drain ion implant region 38 has a constant depth.

In accordance with the embodiments of the present invention, the thickness of the gate spacer and the facets can be constantly controlled and the influence of the facets can be prevented. Therefore, the source/drain region formed by the source/drain ion implantation can be formed with the constant depth, thereby ensuring the stable characteristics of the semiconductor device having the ESD structure.

While the present invention has been described with respect to the specific embodiments, the above embodiments of the present invention are illustrative and should not be construed limiting. It will be apparent to those skilled in the art that various changes and modifications may be made without departing from the spirit and scope of the invention as defined in the following claims.

What is claimed is:

1. A method for fabricating a transistor, comprising:
forming a gate over a substrate;
sequentially forming a first insulation layer and a second insulation layer over the substrate having the gate;
performing a spacer etching process to form an etched first insulation layer and an etched second insulation layer, the etched first insulation layer partially protruding from the substrate and contacting sidewalls of the gate;
removing the etched second insulation layer;
performing a selective epitaxial growth (SEG) process to form an epitaxial layer over the exposed substrate, one of facets of the epitaxial layer being formed on the protruding portion of the etched first insulation layer; and
forming a third insulation layer on sidewalls of the etched first insulation layer, the third insulation layer covering the one of the facets of the epitaxial layer.

2. The method of claim 1, wherein the first insulation layer comprises a nitride layer, and the second and third insulation layers comprise an oxide layer.

3. The method of claim 1, wherein the removing of the etched second insulation layer is performed by a cleaning process using fluorine-based gas or liquid.

4. The method of claim 1, wherein the forming of the epitaxial layer is performed by using a low pressure chemical vapor deposition (LPCVD) apparatus, a very low pressure CVD (VLPCVD) apparatus, a plasma enhanced CVD (PECVD) apparatus, an ultra high vacuum CVD (UHVCVD) apparatus, a rapid thermal CVD (RTCVD) apparatus, or an atmosphere pressure CVD (APCVD).

5. The method of claim 1, wherein the epitaxial layer comprises a doped silicon layer, an undoped silicon layer, a doped silicon germanium layer, or an undoped silicon germanium layer.

6. The method of claim 1, further comprising, after the spacer etch process, performing a cleaning process using a sulfuric peroxide mixture (SPM) or an ammonium peroxide mixture (APM).

7. The method of claim 1, further comprising, after forming of the gate, performing a lightly doped drain (LDD) ion implantation process to form a LDD region.

8. The method of claim 7, wherein the forming of the LDD region comprises:
forming a fourth insulation layer over the substrate where the gate is formed;
forming an etched fourth insulation layer on sidewalls of the gate by performing a spacer etch process;
performing the LDD ion implantation process using the gate and the fourth insulation layer as an ion implantation mask; and
removing the etched fourth insulation layer.

9. The method of claim 8, wherein the forming of the fourth insulation layer is performed by a LPCVD process or a PECVD process.

10. The method of claim 8, wherein the fourth insulation layer comprises an oxide layer.

11. The method of claim 8, wherein the removing of the etched fourth insulation layer is performed by a wet cleaning process or a dry cleaning process.

12. The method of claim 1, further comprising, after the forming of the etched third insulation layer, forming a source/drain region by performing a source/drain ion implantation process using the gate, the etched second insulation layer, and the etched third insulation layer as an ion implantation mask.

13. A semiconductor device, comprising:
a substrate;
a gate formed over the substrate;
gate spacers formed on sidewalls of the gate;
a source/drain region defined on both sides of each gate spacer by a selective growth of an epitaxial layer, the source/drain region being elevated higher than an initial top surface of the substrate,
wherein the gate spacers include an etched first insulation layer contacting the sidewalls of the gate and partially protruding from the substrate, and an etched third insulation layer contacting sidewalls of the etched first insulation layer; and
one of facets of the epitaxial layer formed on the protruding portion of the etched first insulation layer and covered by the etched third insulation layer.

14. The semiconductor device of claim 13, wherein the etched first insulation layer comprises a nitride layer, and the etched third insulation layer comprises an oxide layer.

15. The semiconductor device of claim 13, wherein the epitaxial layer comprises a doped silicon layer, an undoped silicon layer, a doped silicon germanium layer, or an undoped silicon germanium layer.
